(19) United States
(12) Patent Application Publication
(10) Pub. No.: US 2023/0040826 A1
(43) Pub. Date: Feb. 9, 2023

(54) METHOD OF JOINING TWO SEMI-CONDUCTOR SUBSTRATES

(71) Applicant: Soitec, Bernin (FR)

(72) Inventors: Gweltaz Gaudin, Crolles (FR); Céline Futin, Saint Martin d, Heres (FR)

(21) Appl. No.: 17/758,624

(22) PCT Filed: Dec. 15, 2020
(86) PCT No.: PCT/FR2020/052439

§ 371 Date: Jul. 11, 2022

(30) Foreign Application Priority Data
Jan. 9, 2020 (FR) 2000140

(51) Int. Cl. H01L 21/18; H01L 21/324

(52) U.S. Cl. CPC H01L 21/187; H01L 21/324

(57) ABSTRACT

The disclosure relates to a method of joining two semi-conductor substrates by molecular adhesion comprising: a step a) of bringing a first and a second substrate into intimate contact in order to form an assembly having a bonding interface; a step b) of reaction-annealing the bonding interface at a first temperature higher than a predetermined first temperature, this step b) generating bubbles at the joining interface; a step c) of at least partially debonding the two substrates at the bonding interface in order to eliminate the bubbles; and a step d) of bringing the first and the second substrate into intimate contact at the bonding interface in order to reform the assembly.

### CROSS-REFERENCE TO RELATED APPLICATIONS

This application is a national phase entry under 35 U.S.C. § 371 of International Patent Application PCT/FR2020/052439, filed Dec. 15, 2020, designating the United States of America and published as International Patent Publication WO 2021/140285 A1 on Jul. 15, 2021, which claims the benefit under Article 8 of the Patent Cooperation Treaty to French Patent Application Serial No. FR2000140, filed Jan. 9, 2020.

### TECHNICAL FIELD

The present disclosure relates to the field of semiconductor materials for microelectronic components. In particular, it relates to a process for joining two semiconductor substrates by molecular adhesion.

### BACKGROUND

The joining of substrates by molecular adhesion (“direct wafer bonding”) is a well-known technique that has applications in the fields of microelectronics, optoelectronics, and microelectromechanical systems, for example, for manufacturing silicon-on-insulator substrates, multi junction photovoltaic cells, and for producing 3D structures.

According to this technique, two substrates are brought into intimate contact so that their surfaces are brought close enough to one another for atomic and/or molecular bonds to be formed between them. In this way, adhesion forces are created between the two contact surfaces without employing an intermediate adhesion layer such as a polymer or adhesive layer.

The assembly obtained is then generally subjected to a heat treatment at a temperature that may vary between 50° C. and 1200° C., depending on the nature of the substrates and the envisaged application, so as to strengthen the adhesion.

In some cases, joining by molecular adhesion results in the appearance of defects, called bonding defects, at the bonding interface. These may be “bubble”-type defects (“bonding voids”). The bonding defects may result from the trapping and build-up of gaseous species between the surfaces of the joined substrates. These species may correspond to the species adsorbed on the surface of the substrates during their preparation before joining. They may, in particular, correspond to residues from chemical reactions, in particular, from the chemical reaction of water, which occur when the substrates are brought into intimate contact or during the anneal for strengthening the bonding.

The presence of bonding defects at the joining interface is highly detrimental to the quality of the structures produced. For example, when the joining step is followed by a step of thinning one of the two substrates in order to form a layer by milling or using the Smart Cut™ technique, the absence of adhesion between the two surfaces at the location of a bonding defect may lead to the local tearing of the thin layer at this location.

Additionally, when a composite structure, comprising, for example, a thin layer of monocrystalline silicon carbide (SiC) joined to a carrier substrate made of SiC, is intended for the production of vertical power devices, good thermal and electrical conduction between the thin layer and the carrier substrate is required.

To join the substrates that will give rise to the composite structure, there are two main approaches for carrying out direct bonding: the hydrophilic approach and the hydrophobic approach.

In the hydrophilic approach, the surfaces of the two substrates are treated in order to make them hydrophilic by generating, in particular, a layer of native oxide. A layer of water is present between the two substrates in order to promote the formation of atomic and/or molecular bonds that are responsible for the forces of adhesion between the two substrates. However, the presence of the layer of native oxide at the bonding interface affects and worsens the electrical conduction between the two substrates.

In the hydrophobic approach, the surfaces of the two substrates are treated so as to be hydrophobic: the layer of native oxide is removed and the presence of water between the substrates is limited. In order to limit the presence of water still further, the joining between the two substrates may be carried out under a controlled atmosphere, such as an anhydrous atmosphere or vacuum. Two substrates joined together using this approach will exhibit good vertical electrical and thermal conduction (Yushin et al., Applied Physics Letters, 84 (20), 3993-3995, 2004). However, these conditions may be complex to obtain in an industrial environment. Moreover, the applicant has observed that when the two SiC substrates joined using this approach were subjected to a temperature higher than 700° C., pressurized bubbles could form at the interface between the two substrates and negatively affect the quality of the bonding. This is especially troublesome when the assembly formed by joining the two substrates has to be subjected to a heat treatment at a temperature beyond that at which such bubbles appear, for example, in order to perform a layer transfer using the Smart Cut™ method.

There is also another approach based on the bonding of active surfaces (“surface active bonding,” or SAB) as described, for example, by F. Mu et al. (4th IEEE International Workshop on Low Temperature Bonding for 3D Integration (LTB-3D), 15-16 Jul. 2014). The surfaces of the two substrates to be joined are subjected to atom bombardment in order to activate their surfaces before joining them together at a low temperature. This approach makes it possible to obtain a very good force of adhesion between the two substrates but forms an amorphous layer at the interface between the two substrates. The presence of this amorphous layer generally worsens the conductivity between the two substrates.

### BRIEF SUMMARY

The present disclosure relates to a process for joining two semiconductor substrates by molecular adhesion, which allows good electrical and thermal conduction of the joining interface, and which decreases the number of bonding defects or even prevents their appearance entirely.

One embodiment of this disclosure provides a process for joining two semiconductor substrates by molecular adhesion comprising:
a step a) of bringing a first and a second substrate into intimate contact in order to form an assembly exhibiting a bonding interface;
a step b) of reaction-annealing the bonding interface at a first temperature, higher than a predetermined first temperature, this step b) generating bubbles at the bonding interface;
the process being characterized in that it comprises:
a step c) of at least partially debonding the two substrates at the bonding interface in order to eliminate the bubbles;
a step d) of bringing the first and the second substrate back into intimate contact at the bonding interface in order to reform the assembly.

According to other advantageous and non-limiting features of the disclosure taken alone or in any technically feasible combination:
the debonding step c) is performed under a controlled atmosphere;
the controlled atmosphere of the debonding step c) is an anhydrous atmosphere or vacuum;
the debonding step c) is carried out entirely or partly at a second temperature higher than or equal to ambient temperature;
the second temperature is lower than 700° C., preferably lower than 200° C. and even more preferably lower than 100° C.;
the debonding step c) comprises mechanically separating the two substrates by inserting a blade between the two substrates at the bonding interface;
the joining process comprises, after step d), a step e) of thinning the first substrate in order to form a thin layer;
the first substrate comprises a main face and a buried weakened plane, the thin layer being defined between the main face and the buried weakened plane;
step e) comprises splitting along the buried weakened plane in order to transfer the thin layer onto the second substrate;
step e) comprises a heat treatment at a temperature higher than or equal to a predetermined second temperature allowing spontaneous splitting along the buried weakened plane (1b);
the first temperature of step b) and the second temperature of step c) are lower than the predetermined second temperature.

### BRIEF DESCRIPTION OF THE DRAWINGS

Further features and advantages of the disclosure will become apparent from the following detailed description of the invention, with reference to the appended figures, in which:

FIG. 1 shows a composite structure produced according to a joining process in accordance with an embodiment of the disclosure;

FIGS. 2a to 2e show steps in a joining process in accordance with an embodiment of the disclosure; and

FIGS. 3 and 4a to 4e show alternative or optional steps in the joining process in accordance with embodiments of the disclosure.

### DETAILED DESCRIPTION

As mentioned above, the present disclosure relates to a process for joining, by molecular adhesion, a first substrate 1 to a second substrate 2, each substrate being formed from a semiconductor material.

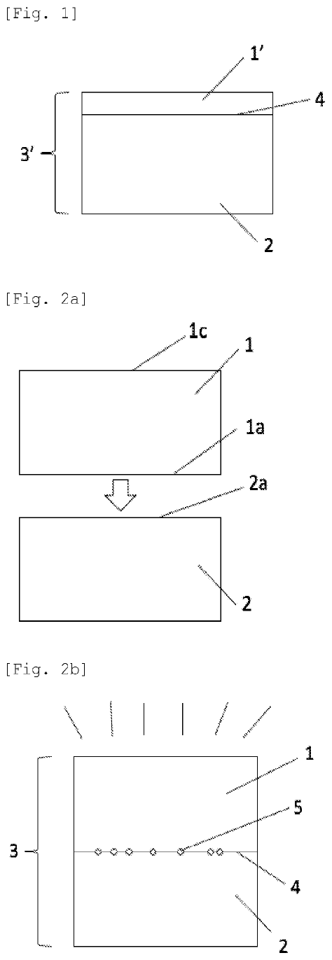

More particularly, the disclosure seeks to form a composite structure 3′ comprising a monocrystalline thin layer 1′ arranged on a carrier substrate 2 (FIG. 1). The first substrate 1 is intended to form the thin layer 1′ in order to produce components, and it is thus preferably formed from a monocrystalline material of good quality. The second substrate 2 is intended to form the carrier substrate 2 of the composite structure 3′, and it may thus be formed from a monocrystalline or polycrystalline material of lower quality.

Advantageously, the thin layer 1′ has a thickness of less than one micrometer, compatible with a SMART CUP®-type method. Before being joined, the first substrate 1 and the second substrate 2 have a thickness on the order of a few hundreds of micrometers.

These two substrates 1, 2 may be formed from different or identical semiconductor materials chosen from silicon carbide (SiC) and indium phosphide (InP). More generally, these materials may be binary, ternary or quaternary compounds formed from elements from column IV and columns III and V of the periodic table of the elements.

The substrates 1, 2 each comprise a “main” face 1a, 2a that corresponds to the faces that will be brought into intimate contact in order to perform the joining.

Before being brought into intimate contact, in order to achieve direct bonding by molecular adhesion, the main surfaces 1a, 2a advantageously undergo various treatments. The aim of these treatments is to clean the main surfaces 1a, 2a in order to remove contaminants (particulate, organic, etc.), and potentially to activate them, in order to promote chemical surface terminations that are favorable to the propagation of the bonding wave and to the high strength of the bonding interface 4. Chemical-mechanical polishing of the main surfaces 1a, 2a may also be applied in order to make the main surfaces 1a, 2a as smooth as possible. It is also conceivable to form, on one of the main surfaces 1a, 2a or on each thereof, an electrically conductive intermediate layer that could also be smoothed by chemical-mechanical polishing.

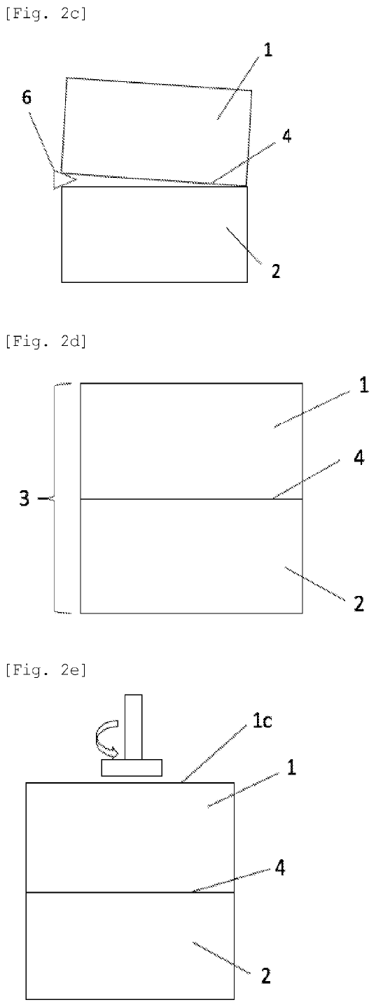

FIGS. 2a to 2e illustrate steps of the joining process according to the disclosure.

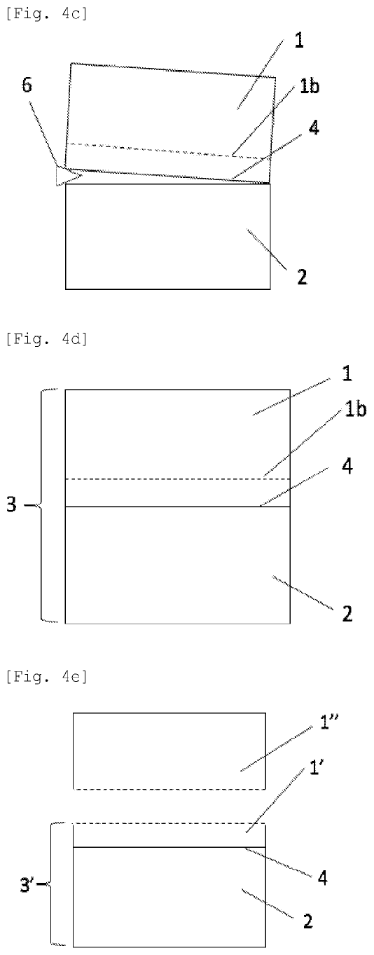

The first step a) (FIGS. 2a and 4a) of the disclosure comprises bringing the main surface 1a of the first substrate 1 into intimate contact with the main surface 2a of the second substrate 2 in order to form an assembly 3 having a bonding interface 4. What is meant by “intimate” contact is the bringing of the main surfaces 1a, 2a into direct contact, without an adhesive layer, in order to join them by molecular adhesion along a bonding interface 4.

The bringing into intimate contact of the substrates 1, 2 may be carried out under ambient atmosphere or under a controlled atmosphere, for example, under inert gas and/or under vacuum. It is conceivable to carry out this bringing into intimate contact at ambient temperature or at a higher temperature, for example, between 30° C. and 500° C.

Upon completion of step a), the assembly 3 is subjected, in the next step b) (FIGS. 2b and 4b), to a reaction anneal of the bonding interface at a temperature (called first temperature hereinafter) higher than a predetermined first temperature. This predetermined first temperature corresponds to the temperature beyond which the species trapped at the bonding interface (for example, hydrogen, fluorine, residues of water monolayers, in the case of hydrophobic bonding) and/or adsorbed prior to bringing into contact, on the main surfaces 1a, 2a, react, fully or partly, to form gas bubbles 5 at the bonding interface 4. The duration of this anneal is typically 1 h.

In the case that the two substrates 1, 2 are formed of SiC, this predetermined first temperature is approximately 200° C., and the first temperature may be chosen, for example, to be equal to 700° C.

The gas trapped in these bubbles 5 may be, for example, dihydrogen, water vapor or carbon dioxide, or other gases arising from the thermally activated reaction at the bonding interface 4. It has been observed that these bubbles 5 are able to remain stable over a wide range of temperatures, typically up to 1100° C., or even higher, in the case of substrates 1, 2 made of SiC. This is problematic, in particular, when a thinning step later in the process has to be carried out without exceeding the aforementioned range in which the bubbles 5 are stable: the bonding defects (corresponding to the bubbles) are liable to harm the integrity and the quality of the thin layer 1′ resulting from the thinning of the first substrate 1.

The next step c) (FIGS. 2c and 4c) of the disclosure comprises the at least partial debonding of the two substrates 1, 2 at the bonding interface 4. Separating the two substrates 1, 2 by opening up the bonding interface 4 allows the bubbles 5 to be eliminated by releasing the gas trapped therein.

The debonding step c) may comprise mechanically separating the two substrates 1, 2 by inserting a blade 6 between the two substrates 1, 2 at the bonding interface 4. The material of the blade is chosen so as to avoid any contamination so as to be compatible with microelectronic applications. The blade is preferably made of Teflon. When it is inserted at the bonding interface 4, the blade 6 generates a debonding wave that propagates along the bonding interface 4 and causes the separation of the two substrates 1, 2. The debonding wave reaches the bubbles 5 present at the interface so as to release the trapped gases and eliminate the bubbles 5. The debonding is, therefore, not necessarily performed over the entire bonding interface 4; the two substrates 1, 2 may thus remain joined over a portion of the bonding interface 4.

This debonding step c) (FIGS. 2c and 4c) is advantageously performed under a controlled atmosphere. It may be carried out in a clean room, or preferably under an anhydrous atmosphere, such as under dry nitrogen or under vacuum, in order to prevent the deposition of particles or water on the main surfaces 1a, 2a of the substrates 1, 2, which might generate bonding defects in the next step.

Step c) may be carried out entirely or partly at a second temperature higher than or equal to ambient temperature. This second temperature is generally lower than 700° C., preferably lower than 200° C. and more preferably lower than 100° C.

Step c) may also comprise a step of ion-beam-etching the main surfaces 1a, 2a of the two substrates 1, 2 in order to remove any oxide layer. This typically involves bombardment with argon ions at an energy from a few tens to a few hundreds of eV for a few tens of seconds.

The two substrates 1, 2 are then brought back into intimate contact at the bonding interface 4 in step d) (FIGS. 2d and 4d) in order to reform the assembly 3 and definitively join the main surfaces 1a, 2a together. This step of bringing back into contact is preferably carried out under a controlled atmosphere that is similar in composition and in temperature to that of step c) in order to avoid introducing new impurities that could generate new bubbles.

After this step d), it will be possible to subject the assembly 3 to heat treatments without generating bonding defects that might negatively affect the quality of the first substrate 1 or of the thin layer 1′ that is obtained upon completion of the optional later thinning step e). This absence of detrimental bonding defects may be explained by the fact that there are now no, or very few, species that are able to react, with temperature, at the bonding interface 4 after definitive joining. Additionally, the precautions taken in steps c) and d) to avoid introducing new impurities also contribute to the absence of bonding defects.

Upon completion of step d), if the target application requires a thin layer 1′ and the initial thickness of the first substrate 1 is not suitable, it is possible to carry out a step e) of thinning the first substrate 1. Being able to subject the assembly 3 to heat treatments without generating bonding defects is especially important if step e) of thinning the first substrate 1 comprises a heat treatment. Indeed, without that, there would be a risk of negatively affecting the quality of the thin layer 1′ resulting from step e).

The aim of step e) (FIGS. 2e and 4e) of thinning the first substrate 1 is to form the thin layer 1′ in which various electronic components might be produced later on.

According to a first embodiment (FIG. 2e), the thin layer 1′ may be formed by thinning the back face 1′ of the first substrate 1 by grinding, dry or wet chemical etching and/or chemical-mechanical polishing, in alternation with cleaning sequences. One (or more) heat treatment(s) may be applied to consolidate the bonding interface 4 and/or to improve the crystal and/or surface quality of the thin layer 1′ without causing the appearance of new bubbles at the bonding interface 4.

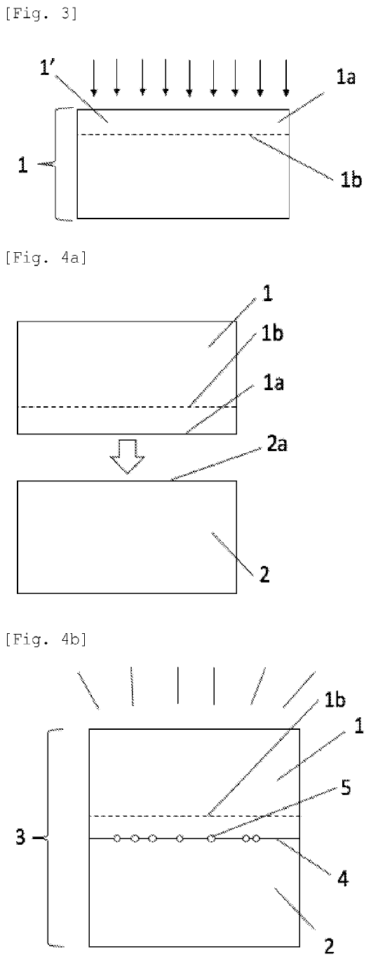

According to a second embodiment, the thin layer 1′ may be formed by layer transfer using the Smart Cut™ method. In this case, the joining process according to the disclosure comprises, before step a) of bringing into intimate contact, a step of forming a buried weakened plane 1b in the first substrate 1 (FIG. 3), the thin layer 1′ then being defined between the main surface 1a and the buried weakened plane 1b. Advantageously, the buried weakened plane 1b is created by ion-implanting light species down to a given depth. The implanted light species are preferentially hydrogen, helium or these two species co-implanted. These light species will form, around the given depth, microcavities distributed in a thin layer parallel to the main surface 1a of the first substrate 1. This thin layer will be called the buried weakened plane 1b, for the sake of simplicity. The energy of implantation of the light species is chosen so as to reach the given depth in the first substrate 1, the depth corresponding to a target thickness of the thin layer 1′.

Steps a) to d) of this second embodiment, illustrated by FIGS. 4a to 4d, are in accordance with the above general description.

Step e) comprises splitting along the buried weakened plane lb in order to separate the thin layer 1′ from the remainder 1″ of the first substrate 1 and thus transfer the thin layer 1′ onto the second substrate 2 (FIG. 4e). This splitting may be induced by applying a heat treatment to the assembly 3, at a temperature higher than or equal to a predetermined second temperature. This predetermined second temperature corresponds to the temperature from which a spontaneous split along the buried weakened plane 1b may occur. It is typically between 750° C. and 1000° C. in the case of a first substrate 1 made of SiC. The splitting heat treatment could have a duration ranging from a few minutes to a few hours. During the heat treatment, the microcavities present in the buried weakened plane 1b follow growth kinetics until the spontaneous initiation of a fracture wave, which will propagate over the entire extent of the buried weakened plane 1b and result in the separation between the thin layer 1′ joined to the second substrate 2 and the remainder 1″ of the first substrate 1. Alternatively, the separation may be induced by applying a localized stress, or by a combination of heat treatment and mechanical stress.

Still according to this second embodiment, it is necessary that the material of the first substrate 1 and the properties of the buried weakened plane 1b (related to the conditions of implantation of the light species) allow a split to be obtained at a second predetermined temperature that is higher than the first temperature of step b) by at least 50° C. to 150° C. in order not to cause premature separation of the thin layer 1′ from the remainder 1″ of the first substrate 1. Similarly, it is necessary that the first temperature of step b) (FIG. 4b) and the second temperature of step c) (FIG. 4c) do not exceed this second predetermined temperature.

Of course, it would be possible to envisage techniques other than those presented above for forming the thin layer 1′ in step e).

Upon completion of the aforementioned steps a) to e), a composite structure 3′ exhibiting no detrimental bonding defects is obtained. The composite structure 3′ obtained thus exhibits a very good force of adhesion between the thin layer 1′ and the carrier substrate 2.

Such a composite structure 3′ may thus be used to form an additional layer thereon by epitaxy, for example, with a thickness of 10 micrometers at 1700° C., in which devices will be formed, without fear of damaging the composite structure 3′.

The composite structure 3′ may also exhibit very good vertical electrical and thermal conduction between the thin layer 1′ and the carrier substrate 2. This is due to the choice of materials for the thin layer 1′ and the carrier substrate 2 and to the absence of an intermediate bonding layer for joining them.

Of course, the disclosure is not limited to the implementation(s) described, and variations may be made thereto without departing from the scope of the invention as defined by the claims.

1. A method for joining two semiconductor substrates by molecular adhesion, the method comprising:
a step a) of bringing a first and a second substrate into intimate contact in order to form an assembly having a bonding interface; and
a step b) of reaction-annealing the bonding interface at a first temperature, higher than a predetermined first temperature, this step b) generating bubbles at the bonding interface;
a debonding step c) of at least partially debonding the first and second substrates at the bonding interface to eliminate the bubbles; and
a step d) of bringing the first and the second substrate back into intimate contact at the bonding interface in order to reform the assembly.

2. The method of claim 1, wherein the debonding step c) is performed under a controlled atmosphere.

3. The method of claim 2, wherein the controlled atmosphere of the debonding step c) comprises an anhydrous atmosphere or vacuum.

4. The method of claim 1, wherein the debonding step c) is carried out at least partially at a second temperature higher than or equal to ambient temperature.

5. The method of claim 4, wherein the second temperature is lower than 700° C.

6. The method of claim 1, wherein the debonding step c) comprises mechanically separating the first and second substrates by inserting a blade between the first and second substrates at the bonding interface.

7. The method of claim 1, further comprising, after step d), a step e) of thinning the first substrate to form a thin layer.

8. The method of claim 7, wherein the first substrate comprises a main face and a buried weakened plane, the thin layer being defined between the main face and the buried weakened plane.

9. The method of claim 8, wherein step e) comprises splitting along the buried weakened plane to transfer the thin layer onto the second substrate.

10. The method of claim 9, wherein:
step e) comprises a heat treatment at a temperature higher than or equal to a predetermined second temperature causing spontaneous splitting along the buried weakened plane; and
the first temperature of step b) and the second temperature of step c) are lower than the predetermined second temperature.

11. The method of claim 4, wherein the debonding step c) is carried out entirely at a second temperature higher than or equal to ambient temperature.

12. The method of claim 5, wherein the second temperature is lower than 200° C.

13. The method of claim 12, wherein the second temperature is lower than 100° C.

14. The method of claim 3, wherein the debonding step c) is carried out at least partially at a second temperature higher than or equal to ambient temperature.

15. The method of claim 14, wherein the second temperature is lower than 700° C.

16. The method of claim 3, wherein the debonding step c) comprises mechanically separating the first and second substrates by inserting a blade between the first and second substrates at the bonding interface.

17. The method of claim 3, further comprising, after step d), a step e) of thinning the first substrate to form a thin layer.

18. The method of claim 17, wherein the first substrate comprises a main face and a buried weakened plane, the thin layer being defined between the main face and the buried weakened plane.

19. The method of claim 18, wherein step e) comprises splitting along the buried weakened plane to transfer the thin layer onto the second substrate.

20. The method of claim 19, wherein:
step e) comprises a heat treatment at a temperature higher than or equal to a predetermined second temperature causing spontaneous splitting along the buried weakened plane; and
the first temperature of step b) and the second temperature of step c) are lower than the predetermined second temperature.
